(19) United States
(12) Patent Application Publication
(10) Pub. No.: US 2026/0123391 A1
(43) Pub. Date: Apr. 30, 2026

(54) METHOD OF MANUFACTURING A MONOLITHIC INTEGRATED CIRCUIT, FOR EXAMPLE BASED ON GALLIUM NITRIDE, AND CORRESPONDING INTEGRATED CIRCUIT

(71) Applicant: STMICROELECTRONICS INTERNATIONAL N.V., Geneva (CH)

(72) Inventors: Valerie VOLANT, Seyssinet-Pariset (FR); Denis COTTIN, Crolles (FR); Patrik ARNO, Sassenage (FR)

(21) Appl. No.: 19/361,917

(22) Filed: Oct. 17, 2025

(30) Foreign Application Priority Data
Oct. 31, 2024 (FR) 2411941

(51) Int. Cl. H01L 23/528; H01L 21/768; H01L 23/00

(52) U.S. Cl. CPC H10W 20/43; H10W 20/032; H10W 72/20

(57) ABSTRACT

A method of manufacturing a monolithic integrated circuit is provided. An example method includes: the formation of functional blocks within and on top of at least one wide-bandgap semiconductor material deposited on a silicon substrate, forming mutually separated interconnecting parts on top of the functional blocks, separating the functional blocks, and forming an electrically conductive connection between the substrate and a contact pad located on a top face of the interconnecting part associated with a functional block. The separation of functional blocks and forming the electrically conductive connection are performed after the formation of the mutually separated interconnecting parts.

### CROSS REFERENCE TO RELATED APPLICATION(S)

This application claims the priority benefit of French patent application number FR2411941, filed on Oct. 31, 2024, entitled “PROCEDE DE FABRICATION D'UN CIRCUIT INTEGRE MONOLITHIQUE, PAR EXEMPLE A BASE DE NITRURE DE GALLIUM, ET CIRCUIT INTEGRE CORRESPONDANT”, which is hereby incorporated by reference to the maximum extent allowable by law.

### TECHNICAL FIELD

The present disclosure relates to integrated circuits, in particular monolithic integrated circuits and in particular those incorporating functional blocks produced on wide-bandgap semiconductor materials on a silicon substrate, for example materials such as gallium nitride (GaN) and its alloys or silicon carbide (SiC) and its alloys, however these examples of materials are not in any way exhaustive or limiting.

Together such functional blocks can form an electronic device for example.

### BACKGROUND

When gallium nitride (GaN) and its alloys are used in such a device, it is referred to more simply as a GaN device.

When silicon carbide (SiC) and its alloys are used in such a device, it is referred to more simply as a SiC device.

One such electronic device is a switched-mode power supply (DC-DC converter).

In a switched-mode power supply, the functional blocks may comprise:
transistors, generally High Electron Mobility Transistors (HEMT),
drivers,
etc . . . Some of these HEMT transistors are High Side (HS) transistors, i.e. connected between the load and the supply voltage.

Other HEMT transistors are Low Side (LS) transistors, i.e. connected between the load and ground.

There are several integration possibilities for combining different functional blocks to form GaN devices or SiC devices.

An example of this is discrete integration, in which a plurality of discrete components are inserted into a package.

Another example is monolithic integration, in which power, drive and other functions are designed into the same chip.

Furthermore, Wafer-Level Chip Scale Packaging (WL-CSP), in which the chip is not encapsulated in a package, is of great interest due to its small footprint and small amount of electrical connections, thereby reducing parasitic inductance, noise and leakages.

The trend in the market for products based on wide band-gap materials, for example materials based on gallium nitride, is directed towards ever smaller packages with high-performance features such as high output current, low leakages and high power consumption efficiency, which provides a solution to many problems.

A first problem to be solved relates to the physical separation of layers of wide-bandgap materials.

Indeed, power components based on gallium nitride for example are based on the structuring of gallium nitride layers deposited over the entire silicon wafer.

However, when the HS and LS transistors and additional drivers are combined on the same monolithic chip, these functional blocks need to be physically separated without any link between the low-voltage and high-voltage (LS and HS) parts and between the HS and LS transistors and the drivers.

This physical separation is necessary to avoid leakages and breakdown voltages.

A second problem to be solved relates to the polarisation of the silicon substrate.

Indeed, when the electronic device is integrated into a system, the silicon substrate needs to be connected to ground or be polarised to obtain acceptable device behaviour, by avoiding as far as possible problems of leakage and noise affecting the performance of the device.

In this respect, the silicon substrate has to be polarised, for example connected to ground, and cannot be left floating, as the threshold voltage of GaN power devices depends on the polarisation of the silicon substrate.

The third problem relates to the length of the electrical interconnections.

Indeed, the electrical interconnections inside the device have to be kept as short as possible, to avoid parasitic inductances that could cause power surges during power transistor switching as well as electromagnetic interference.

A fourth problem relates to the footprint of the device, which needs to be as small as possible.

The first problem and the second problem mentioned above are solved or do not exist with discrete component integration.

However, the third problem and the fourth problem mentioned above remain difficult to solve.

For this reason, it is particularly advantageous to move towards solutions using monolithic components, i.e. components in which all functional blocks are formed within a single chip.

This makes it possible to solve the third and the fourth problem mentioned above.

However, for all of these monolithic solutions, the first problem and the second problem mentioned above need to be solved at the chip level, as the layers of wide-bandgap materials cover the entire surface of the chip.

The manufacture of a monolithic integrated circuit including layers of wide-bandgap materials, for example layers of materials containing gallium nitride, includes a plurality of steps.

All of these steps are performed on a silicon wafer including cutting lines, which once the wafer has been cut along these cutting lines, enable all the individual integrated circuits to be produced simultaneously in the locations delimited by these cutting lines.

Generally, in a first phase, the silicon wafer is firstly stacked with layers of wide-bandgap materials, then the various components and functional blocks, including transistors, drivers etc., are produced.

In this first phase, the interconnecting parts known to the person skilled in the art as Back End Of Line (BEOL) are produced on top of these components, including levels of metal and vias between these levels of metal, all of the levels being encapsulated in a dielectric material.

The last level of metal is typically covered by a passivation layer, for example of silicon nitride, including openings delimiting contact pads on the last metal level.

Then, in a second manufacturing phase, connecting balls are formed on these contact pads, for subsequent soldering to a printed circuit board.

Currently, the physical separation of the functional blocks and from their respective interconnecting part, as well as the polarisation of the silicon substrate, are carried out by specific steps within this first phase of manufacturing integrated circuits.

However, these specific steps are industrially complex to implement.

### BRIEF SUMMARY

It is therefore necessary to perform this physical separation as well as the polarisation of the silicon substrate in a simpler way which is easy to implement industrially.

In this respect, the inventors have observed that it is possible to carry out these separation and polarisation steps in the second phase of producing integrated circuit before the connecting balls are formed.

This allows more flexible industrialisation at lower cost.

According to one aspect, a method is proposed for manufacturing a monolithic integrated circuit.

The method comprises the production of functional blocks, for example but without being in any way exhaustive or limiting, HS and LS HEMT transistors, drivers etc..., within and on top of at least one wide-bandgap semiconductor material, for example a stack of layers of such a material and its alloys, arranged on a silicon substrate.

The method further comprises:
making interconnecting parts (known to the person skilled in the art by the acronym BEOL) mutually separated on top of the functional blocks, and
making an electrically conductive connection between the substrate and a contact pad located on a top face of an interconnecting part.

In the method according to this aspect, the separation of the functional blocks and the formation of the electrically conductive connection are performed after the formation of the mutually separated interconnecting parts.

With regard to the monolithic integrated circuit itself, the person skilled in the art knows that after each interconnecting part has been produced, the last metal level is partially covered by a passivation layer, typically a layer of silicon nitride, forming a top face of the corresponding interconnecting part and having openings delimiting contact pads on the last metal level.

The fact that the separation of the functional blocks and the electrically conductive connection is performed after the interconnecting parts have been produced, also means that trenches without a passivation layer are obtained in the integrated circuit, as well as a metal layer extending the last metal level, as is the case in the methods according to the prior art.

According to one implementation mode of the method, the formation of the electrically conductive connection comprises:
forming a first deep trench located next to the contact pad and extending from the top face of the interconnecting part to the substrate, and
forming an electrically conductive layer, typically a redistribution layer including copper for example, lining the bottom of the first deep trench in contact with the substrate as well as the side wall of this first deep trench and extending over the top face of the interconnecting part to the contact pad.

According to one embodiment, the formation of two separate interconnecting parts, on top of two adjacent functional blocks, includes the formation of an initial trench between the two interconnecting parts and the separation includes:
forming an additional trench between the two adjacent functional blocks, lengthening the initial trench and extending up to the substrate by traversing the at least one wide-bandgap semiconductor material, the initial trench and the additional trench forming a second deep trench, and
forming an electrically insulating layer, typically a polyimide layer, located on top of the side wall and bottom of the second deep trench.

According to one implementation mode:
the electrically conductive layer (typically the redistribution layer) is formed on the walls of the first deep trench and the second deep trench and on the top face of the two interconnecting parts, then
a first part of this electrically conductive layer is removed from the second deep trench so as to expose part of the bottom and side wall of this second deep trench and to leave a second part of the electrically conductive layer on the remainder of the bottom and the side wall of this second deep trench, then
the electrically insulating layer (typically the polyimide layer) is formed so as to cover the electrically conductive layer with the exception of areas located on top of the contact pads and to cover the uncovered part of the bottom and side wall of the second deep trench.

The method also comprises, according to one embodiment, forming connecting balls on top of portions of the electrically conductive layer (typically the redistribution layer) located on top of the contact pads.

According to a preferred implementation mode, in which the integrated circuit is manufactured simultaneously with other integrated circuits on a semiconductor wafer within locations separated by cutting lines, prior to sawing the wafer along cutting lines, along these cutting lines and simultaneously with the production of the first and second deep trenches, separation trenches are produced extending up to the substrate traversing the at least one wide-bandgap semiconductor material.

The at least one wide-bandgap semiconductor material can be selected from the group including gallium nitride (GaN) and its alloys and silicon carbide (SiC) and its alloys.

According to another aspect, a monolithic integrated circuit is proposed, comprising
a plurality of functional blocks within and on top of at least one wide-bandgap semiconductor material disposed on a silicon substrate,
an interconnecting part on top of each functional block including a plurality of metal levels, the last metal layer being partially covered by a passivation layer forming a top face of the interconnecting part and having openings delimiting contact pads on the last metal level,
an electrically conductive connection between a contact pad and the substrate, and
separation means of functional blocks.

According to this aspect,
the electrically conductive connection includes a first deep trench extending from the top face of the interconnecting part including the contact pad to the substrate and not having the passivation layer, and
the separation means include a second deep trench located between two adjacent functional blocks, extending between the two interconnecting parts associated with these two functional blocks to the substrate traversing the at least one wide-bandgap semiconductor material, this second deep trench also being without a passivation layer.

The first deep trench and the second deep trench are also advantageously without a metal layer extending the last metal level.

According to one embodiment:
the electrically conductive connection comprises an electrically conductive layer (for example a redistribution layer) lining the bottom of the first deep trench in contact with the substrate as well as the side wall of this first deep trench and extending on the top face of the interconnecting part up to the contact pad, and
the separation means an electrically insulating layer, for example a polyimide layer, located on top of the side wall and the bottom of the second deep trench.

According to one embodiment, part of the bottom and side wall of the second deep trench is covered by part of the electrically conductive layer (for example part of the redistribution layer) and this part of the electrically conductive layer as well as the remainder of the bottom and the side wall of this second deep trench are covered by the electrically insulating layer (for example the polyimide layer), this electrically insulating layer also covering the remainder of the electrically conductive layer with the exception of the areas located on top of the contact pads.

According to one embodiment, the integrated circuit also comprises connecting balls on top of the portions of the electrically conductive layer located on top of the contact pads.

The at least one wide-bandgap semiconductor material is selected for example from the group including gallium nitride and its alloys and silicon carbide and its alloys.

According to another aspect, an integrated switching power device is proposed, including the integrated circuit as defined above.

### BACKGROUND

Other advantages and features of the present disclosure will appear on examining the detailed description of non-limiting modes of implementation and embodiments, and from the appended drawings, wherein:

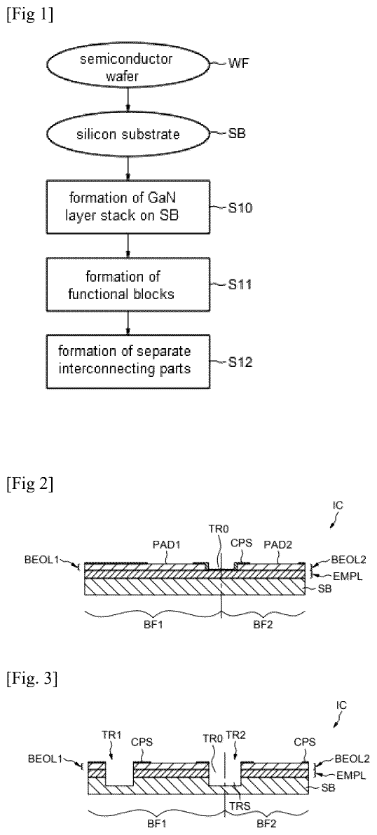

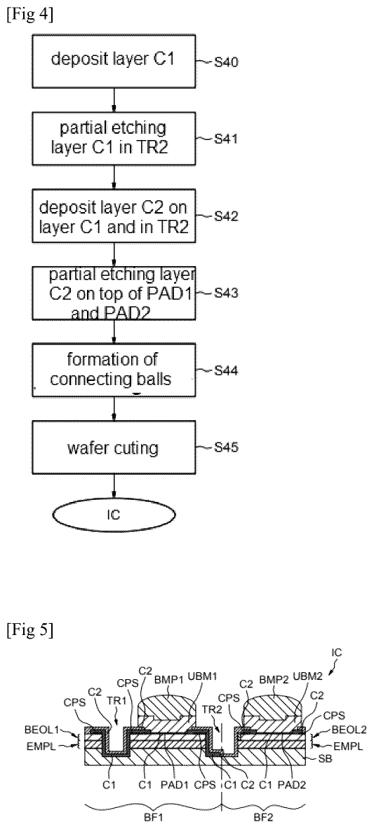

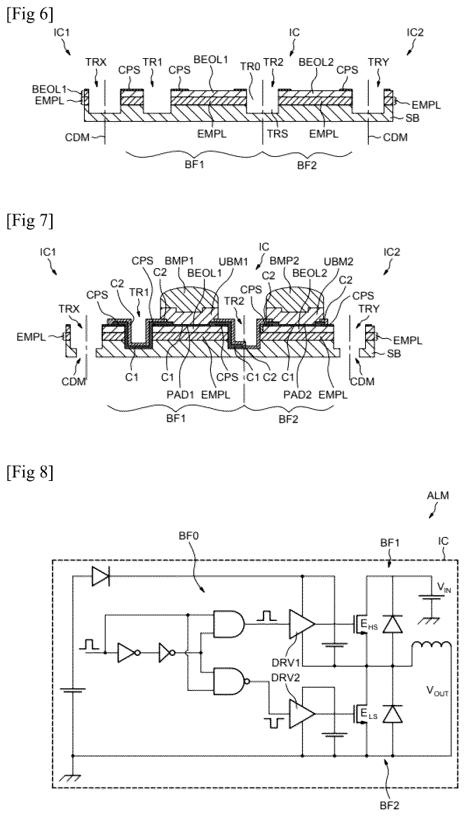

FIG. 1, FIG. 2, FIG. 3, FIG. 4, FIG. 5, FIG. 6, FIG. 7, and FIG. 8 illustrate implementation modes and embodiments of the present disclosure.

### DETAILED DESCRIPTION

FIG. 1 illustrates the steps of a first phase of a method for manufacturing an integrated circuit according to the present disclosure.

As known by the person skilled in the art, a plurality of identical integrated circuits are manufactured simultaneously on a semiconductor wafer.

The wafer includes cutting lines defining the locations on which the identical integrated circuits will be produced simultaneously. After manufacture, these are then individualised by sawing the wafer along the cutting lines.

In the following, for simplicity, only one of these integrated circuits will be described here.

In step S10, a stack of layers of a wide-bandgap semiconductor material and its alloys, in this case a stack of layers of gallium nitride GaN and its alloys, is formed on the semiconductor wafer WF including a silicon substrate SB, for example a P-doped substrate.

More precisely, after having deposited a layer of aluminium nitride (AlN) on the top face of the substrate SB, several layers of an aluminium gallium nitride alloy (AlGaN) are deposited.

Then, these layers of AlGaN are covered by a layer of gallium nitride (GaN), itself covered by another thin AlGaN layer.

In step S11, the various functional blocks of the integrated circuit are formed in a conventional known manner.

By way of a non-limiting example, and as illustrated very schematically in FIG. 8, the integrated circuit IC may be designed to incorporate an ALM power supply.

In this case, the various functional blocks may include a BF1 block containing a HS HEMT transistor, referenced as EHS, a BF2 block containing a LS HEMT transistor, referenced as ELS, as well as a functional block BF0 incorporating the DRV1 and DRV2 drivers.

Then in step S12, an interconnecting part is formed on top of each functional block, the interconnecting parts being mutually separated.

This first phase of the manufacturing method produces the integrated circuit IC illustrated schematically in FIG. 2.

In this FIG. 2, for simplicity, only two functional blocks BF1 and BF2 are shown.

The reference SB denotes the silicon substrate.

This silicon substrate is topped by the aforementioned EMPL stack of GaN-type layers, on top of and within which the various functional block components are formed.

For simplicity, these different components are not shown in FIG. 2.

In this respect, the reference EMPL generally denotes the stack of GaN-type layers as well as the various components of the functional blocks.

The top part of FIG. 2 illustrates very schematically the interconnecting part BEOL1 associated with the functional block BF1 and the interconnecting part BEOL2 associated with the functional block BF2.

These two interconnecting parts are separated by an initial trench TR0.

Furthermore, a passivation layer CPS, for example made of silicon nitride, covers the last metal level of the interconnecting part BEOL1, the last metal level of the interconnecting part BEOL2 and lines the walls (side walls and bottom wall) of the initial trench TR0.

This layer CPS includes openings delimiting the contact pads on the last metal level of each interconnecting part.

For simplification of the figure, only one contact pad PAD1 is shown in FIG. 2 for the interconnecting part BEOL1 and only one contact pad PAD2 is shown in this FIG. 2 for the interconnecting part BEOL2.

As illustrated in FIG. 3, in the integrated circuit IC of FIG. 2, a first deep trench TR1 is formed extending from the top face of the interconnecting part BEOL1 to the substrate SB.

Likewise, the initial trench TR0 is extended by a further trench TRS so as to reach the substrate SB and thus form a second deep trench TR2.

These trenches are formed by any means known by the person skilled in the art, for example advantageously by laser dicing or plasma dicing.

Laser dicing, also known as laser grooving, is the laser ablation of GaN-type layers of the stack EMPL.

As will be seen in more detail below, the first deep trench TR1 will help polarise the substrate SB from the top of the integrated circuit, while the second deep trench TR2 will contribute to the physical separation of the functional blocks BF1 and BF2.

As the trenches TR1 and TR2 are formed at this stage of the method, these trenches TR1 and TR2 do not have on their wall, passivation layers CPS as well as metal layers from the last metal level of the interconnecting parts BEOL1 and BEOL2, and this is contrary to the methods of the prior art which lead to the presence in such trenches of a residue of passivation layers and metal from the last metallisation level of the interconnecting parts.

Reference is now made to in particular to FIGS. 4 and 5 to describe a second phase of the method of manufacturing the integrated circuit.

In step S40 (FIG. 4), an electrically conductive layer C1 (FIG. 5) is deposited over the entire surface of the wafer and consequently in trenches TR1 and TR2, for example a redistribution layer known to the person skilled in the art by the acronym RDL (ReDistribution Layer).

Then, as illustrated in FIG. 5, step S41 involves partial etching of the layer C1 in the second deep trench TR2 so as to uncover a part of the bottom of the second deep trench TR2 and part of the side wall of this second deep trench TR2, in this case of the side wall adjacent to the second functional block BF2.

Then, in step S42, an electrically insulating layer C2 is deposited on the layer C1 and on the uncovered parts of the bottom and side wall of the second deep trench TR2.

This insulating layer C2 is for example a polyimide layer.

Then, in step S43, this layer C2 is partially etched on top of the contact pads PAD1 and PAD2 (FIG. 5).

At this stage, the contact pads PAD1 and PAD2 are covered by part of the redistribution layer C1.

Then step S44 involves forming connecting balls on the contact pads.

FIG. 5 shows two connecting balls BMP1 and BMP2.

To produce these connecting balls, a metal layer UBM1, UBM2, known to the person skilled in the art as Under Ball Metal (UBM), can be formed on top of the redistribution layer C1.

These metal layers UBM1 and UBM2 are therefore located under the connecting balls BMP1 and BMP2.

It should also be noted that, as illustrated in FIG. 5, parts of the layer C1 located around the first deep trench TR1 (apart from the part leading to the metal layer UBM1), and around the metal layer UBM2, have also been removed so that contact with the substrate SB is only made in areas of interest to avoid short-circuiting the entire chip surface.

Step S45 is a wafer cutting step along the cutting lines, to individualise the integrated circuits.

After the individualisation of the integrated circuits, the integrated circuit IC illustrated in FIG. 5 is obtained.

FIG. 5 shows that the substrate SB can be polarised by means of the connecting ball BMP1 and the redistribution layer C1 which is in contact with the substrate SB at the bottom of the first deep trench TR1.

Furthermore, the two functional blocks BF1 and BF2 are separated physically and electrically by the insulating layer C2 which lines the second deep trench TR2.

The method described above makes it possible to simplify the first manufacturing phase illustrated in FIG. 1 and to industrialise it flexibly at a lower cost, in particular by using a laser to form the deep trenches TR1 and TR2. Furthermore, the final electronic device performs better due to the flexible placement of the first deep trench TR1 used for the polarisation of the substrate SB.

Of course, other wide-bandgap materials are also possible, such as for example silicon carbide (SiC) and its alloys.

The present disclosure is not limited to the embodiments described above but covers all variants thereof.

A particularly advantageous variant relates more particularly to the individualisation of integrated circuits of the wafer and will now be described with particular reference to FIGS. 6 and 7.

Prior to the conventional sawing along the cutting lines, it is advisable to remove the GaN or SiC-type layers from the stack along these cutting lines by laser or plasma etching, in order to avoid cracks in the integrated circuits.

Thus, as illustrated in FIG. 6, which shows the integrated circuit IC of FIG. 3 framed by two other integrated circuits IC1 and IC2 of the wafer, this removal can advantageously be carried out simultaneously with the formation of the trenches TR1 and TR2, which makes it possible to avoid the need for a specific additional step later in the method and thus provides an additional industrial advantage over those already mentioned above.

More precisely, at the same time as forming the trenches TR1 and TR2, separation trenches TRX and TRY are made along the cutting lines or paths CDM separating the integrated circuits IC1, IC, IC2, trenches extending up to the substrate SB traversing the stack, which makes it possible to remove GaN or SiC layers form the stack between the integrated circuits.

Then, as shown in FIG. 7, the ICs IC1 and IC2 are individualised by conventional mechanical sawing of the wafer along the cutting lines or paths CDM.

As indicated above, the electronic devices integrated on an integrated circuit IC of the type just described can be of various types.

In particular, an ALM switching power supply (FIG. 8) can be obtained, the classic layout of which is shown in FIG. 8.

More precisely, from an input voltage V_{IN}, an output voltage VOUT is obtained using “high-side” transistors EHS and “low-side” transistors ELS, conventionally connected to an inductor and driven by driver circuits DRV1 and DRV2, themselves controlled by pulse-width modulation.

1. A method of manufacturing a monolithic integrated circuit, comprising forming functional blocks within and on top of at least one wide-bandgap semiconductor material arranged on a silicon substrate, forming mutually separated interconnecting parts on top of the functional blocks, separating the functional blocks, and forming an electrically conductive connection between the silicon substrate and a contact pad located on a top face of an interconnecting part associated with a functional block, a method in which the separation of the functional blocks and the formation of the electrically conductive connection are performed after the formation of mutually separated interconnecting parts;
wherein the formation of the electrically conductive connection comprises:
making a first deep trench located next to the contact pad and extending from the top face of the interconnecting part up to the silicon substrate,
forming an electrically conductive layer lining a bottom of the first deep trench in contact with the silicon substrate, as well as a side wall of the first deep trench and extending on the top face of the interconnecting part up to the contact pad; and
wherein a formation of two separated interconnecting parts on top of two adjacent functional blocks includes forming an initial trench between the two separated interconnecting parts, and the separation includes:
forming an additional trench located between the two adjacent functional blocks, extending the initial trench and extending up to the silicon substrate traversing the at least one wide-bandgap semiconductor material, the initial trench and the additional trench forming a second deep trench, and
forming an electrically insulating layer located on top of the side wall and bottom of the second deep trench.

2. The method according to claim 1, wherein the electrically conductive layer is formed on the walls of the first deep trench and the second deep trench and on the top face of the two separated interconnecting parts;
wherein a first part of the electrically conductive layer is removed from the second deep trench so as to uncover a part of the bottom and the side wall of the second deep trench and leave a second part of the electrically conductive layer on a remainder of the bottom and the side wall of the second deep trench; and
wherein the electrically insulating layer is formed to cover the electrically conductive layer with an exception of areas located on top of one or more contact pads and cover an uncovered part of the bottom and the side wall of the second deep trench.

3. The method according to claim 2, further comprising forming connecting balls on top of one or more portions of the electrically conductive layer located on top of the contact pads.

4. The method according to claim 1, wherein the monolithic integrated circuit is manufactured simultaneously with one or more other monolithic integrated circuits on a semiconductor wafer within locations separated by cutting lines and prior to sawing the semiconductor wafer along the cutting lines, separation trenches are created along these cutting lines and simultaneously with the formation of the first deep trench and second deep trench, extending as far as the silicon substrate traversing the at least one wide-bandgap semiconductor material.

5. The method according to claim 1, wherein the at least one wide-bandgap semiconductor material is selected from a group comprising gallium nitride and its alloys and silicon carbide and its alloys.

6. A monolithic integrated circuit, comprising:
a plurality of functional blocks within and on top of at least one wide-bandgap semiconductor material disposed on a silicon substrate;
an interconnecting part on top of each functional block of the plurality of functional blocks including a plurality of metal levels, a last metal level being partially covered by a passivation layer forming a top face of the interconnecting part and having openings delimiting contact pads on the last metal level;
an electrically conductive connection between a contact pad and the silicon substrate; and
means for separating the plurality of functional blocks:
wherein the electrically conductive connection includes a first deep trench extending from the top face of the interconnecting part to the silicon substrate and without the passivation layer; and
wherein the means for separating the plurality of functional blocks include a second deep trench located between two adjacent functional blocks, extending between two interconnecting parts associated with these two functional blocks as far as the silicon substrate through the at least one wide-bandgap semiconductor material, the second deep trench also being without a passivation layer.

7. The monolithic integrated circuit according to claim 6, wherein the first deep trench and the second deep trench are without a metal layer extending the last metal level.

8. The monolithic integrated circuit according to claim 6, wherein
the electrically conductive connection comprises an electrically conductive layer lining a bottom of the first deep trench in contact with the silicon substrate as well as a side wall of the first deep trench and extending on the top face of the interconnecting part up to the contact pad, and
the means for separating the plurality of functional blocks includes an electrically insulating layer located on top of the side wall and the bottom of the second deep trench.

9. The monolithic integrated circuit according to claim 8, wherein a part of the bottom and the side wall of the second deep trench is covered by a part of the electrically conductive layer and the part of the electrically conductive layer as well as a rest of the bottom and the side wall of the second deep trench are covered by the electrically insulating layer, the electrically insulating layer also covering the rest of the electrically conductive layer with an exception of areas located on top of the contact pads.

10. The monolithic integrated circuit according to claim 9, further comprising connecting balls on top of the portions of the electrically conductive layer located on top of the contact pads.

11. The monolithic integrated circuit according to claim 6, wherein the at least one wide-bandgap semiconductor material is selected from a group comprising gallium nitride and its alloys and silicon carbide and its alloys.

12. An integrated switching power supply device, including the monolithic integrated circuit according to claim 6.
